(19) United States
(12) Patent Application Publication
(10) Pub. No.: US 2025/0236986 A1
(43) Pub. Date: Jul. 24, 2025

(54) HOTZONE COMPONENTS HAVING A PROTECTIVE COATING

(71) Applicant: GlobalWafers Co., Ltd., Hsinchu (TW)

(72) Inventor: Richard Joseph Phillips, St. Peters, MO (US)

(21) Appl. No.: 19/015,098

(22) Filed: Jan. 9, 2025

Related U.S. Application Data
(60) Provisional application No. 63/622,964, filed on Jan. 19, 2024.

(51) Int. Cl. C30B 15/14; C30B 29/06

(52) U.S. Cl. CPC C30B 15/14; C30B 29/06

(57) ABSTRACT

Graphite hotzone components of an ingot puller apparatus are disclosed. The graphite hotzone components have a hafnia coating disposed on one or more surfaces of the components. Example components that include a hafnia coating include heater assemblies, insulation and/or reflectors that shroud the crystal.

### CROSS-REFERENCE TO RELATED APPLICATIONS

This application claims the benefit of U.S. Provisional Patent Application No. 63/622,964, filed Jan. 19, 2024, which is incorporated herein by reference in its entirety.

### TECHNICAL FIELD

The field of the disclosure relates to hotzone components of an ingot puller apparatus and, in particular, to graphite hotzone components that include a protective coating disposed thereon.

### BACKGROUND

Single crystal silicon ingots may be grown by the so-called Czochralski process in which a silicon seed crystal is contacted with a melt of silicon. The silicon seed crystal is withdrawn from the melt causing a single crystal silicon ingot suspended by the seed crystal to form. The silicon seed crystal is secured to a seed chuck that is connected to a pull cable. The pull cable supports the chuck and seed crystal (and ingot during crystal growth). The pull cable is connected to a pulling mechanism which lowers and raises the pull cable within the ingot puller apparatus.

The ingot puller apparatus includes an inner chamber or “hotzone” that is insulated and/or includes heat shields at its perimeter to maintain the high temperature of the ingot puller apparatus within the hotzone. Disposed within the hotzone are various graphite components that support the functions of the ingot puller apparatus and/or that assist in maintaining the temperature of the hotzone. Example components within the hotzone that are made of graphite include side and/or bottom heaters, insulation (e.g., rigid bottom insulation and/or rigid side insulation), exhaust ports, and reflector supports.

The silicon melt produces SiO gas which reacts with carbon materials such as graphite through carbon monoxide (CO(g)) formation. This causes reduction in heater lifetime through cross-sectional thinning. Reduction in heater cross-section is compensated by adjustment of heater power to achieve consistent crystal growth which complicates crystal growth processes. Reaction of SiO(g) with insulation causes the insulation to become embrittled due to porosity changes which reduces the insulating capability and causes the insulation to be susceptible to mechanical damage when removed from the hotzone. Degradation may cause graphite components above the melt (such as reflectors) to crack. Graphite components in contact with quartz (e.g., graphite susceptors that contact quartz crucibles) also react and yield SiO(g) and CO(g). Susceptor and quartz crucible erosion may cause melt spills which damage additional ingot puller components.

Silicon carbide may be used to coat graphite components in the hotzone (e.g., reflectors). Silicon carbide may also react with the ambient of the ingot puller apparatus but a rate less than graphite. Other coatings such as boron nitride (BN) may be used but the coatings are difficult to densify which increases the risk of the coating dislodging and contaminating the melt.

A need exists for new coatings for hotzone components that increase lifetime of the components and that achieve sufficient densification to reduce or prevent contamination of the melt and incorporation of the coating material into the growing crystal.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to an ingot puller apparatus for producing a single crystal silicon ingot. The ingot puller apparatus includes a crucible assembly for holding a silicon melt. An ingot puller housing defines a growth chamber for pulling a silicon ingot from the silicon melt. The crucible assembly is disposed within the growth chamber. A heater assembly is disposed external to the crucible assembly. The heater assembly is an electrically resistive heater comprising a graphite substrate. The graphite substrate is coated with hafnia.

Another aspect of the present disclosure is directed to an ingot puller apparatus for producing a single crystal silicon ingot. The ingot puller apparatus includes a crucible assembly for holding a silicon melt. An ingot puller housing defines a growth chamber for pulling a silicon ingot from the silicon melt. The crucible assembly is disposed within the growth chamber. Insulation is disposed along one or more inner surfaces of the ingot puller housing. The insulation comprises graphite coated with hafnia.

Yet another aspect of the present disclosure is directed to an ingot puller apparatus for producing a single crystal silicon ingot. The ingot puller apparatus includes a crucible assembly for holding a silicon melt. An ingot puller housing defines a growth chamber for pulling a silicon ingot from the silicon melt. The crucible assembly is disposed within the growth chamber. A reflector assembly has an opening for receiving the single crystal silicon ingot as the ingot is pulled through the reflector assembly. The reflector assembly comprises molybdenum coated with hafnia.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a is a cross-section of an ingot puller apparatus during ingot growth;

FIG. 2 is a cross-section of a side heater of an ingot puller apparatus; and

FIG. 3 shows quartz cubes supported on hafnia-coated graphite coupons (CVD and plasma sprayed) and a non-coated graphite coupon.

Corresponding reference characters indicate corresponding parts throughout the drawings.

### DETAILED DESCRIPTION

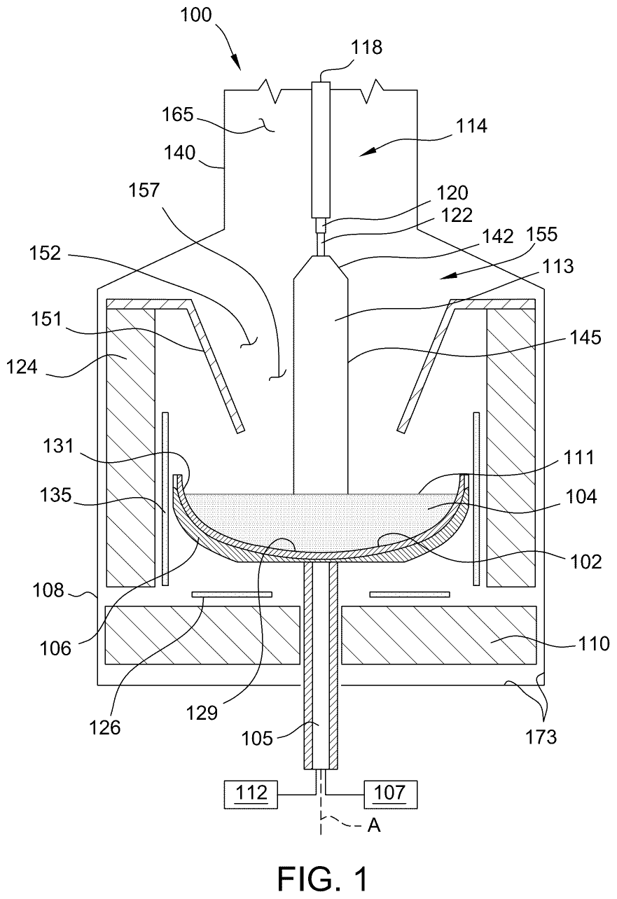

Provisions of the present disclosure relate to ingot puller apparatus having one or more hotzone components that are coated with hafnia to increase the lifetime of the component. An example ingot puller apparatus (or more simply “ingot puller”) is indicated generally as “100” in FIG. 1. The ingot puller apparatus 100 includes a crucible assembly 102 for holding a melt 104 of semiconductor or solar-grade silicon. The crucible assembly 102 is supported by a susceptor 106.

The ingot puller apparatus 100 includes an ingot puller housing 108 that defines a growth chamber 152 for pulling a silicon ingot from the silicon melt 104 along a pull axis A. The growth chamber 152 includes two portions—a lower growth chamber 155 (or simply “lower chamber”) and an upper growth chamber 165 (or simply “upper chamber”) disposed above the lower growth chamber 155. The hotzone of the ingot puller apparatus 100 (e.g., including reflector assembly, susceptor, heaters, and the like) is disposed within the lower chamber 155. During ingot growth, the ingot 113 is pulled through the lower chamber 155 and continues to be pulled through the upper chamber 165 as the ingot lengthens.

The crucible assembly 102 is disposed in the lower chamber 155. The crucible assembly 102 has a sidewall 131 and floor 129 and rests on a susceptor 106. The susceptor 106 is supported by a shaft 105. The susceptor 106, crucible assembly 102, shaft 105, and ingot 113 have a common longitudinal axis or “pull axis” A.

A pulling mechanism 114 is provided within the ingot puller apparatus 100 for growing and pulling an ingot 113 from the melt 104. The pulling mechanism 114 includes a pull cable 118, a seed holder or chuck 120 coupled to one end of the pull cable 118, and a seed crystal 122 coupled to the chuck 120 for initiating crystal growth. One end of the pull cable 118 is connected to a pulley (not shown) or a drum (not shown) of the pulling mechanism 114 and the other end is connected to the chuck 120 that holds the seed crystal 122. The pulling mechanism 114 includes a motor that rotates the pulley or drum.

In operation, the seed crystal 122 is lowered to contact the surface 111 of the melt 104. The pulling mechanism 114 is operated to cause the seed crystal 122 to rise. This causes a single crystal ingot 113 to be pulled from the melt 104.

During heating and crystal pulling, a crucible drive unit 107 (e.g., a motor) rotates the crucible assembly 102 and susceptor 106. A lift mechanism 112 raises and lowers the crucible assembly 102 along the pull axis A during the growth process. For example, the crucible assembly 102 may be at a lowest position (near a bottom heater 126) in which a charge of solid-phase silicon previously added to the crucible assembly 102 is melted. Crystal growth commences by contacting the melt 104 with the seed crystal 122 and lifting the seed crystal 122 by the pulling mechanism 114.

A crystal drive unit (not shown) may also rotate the pulling cable 118 and ingot 113 in a direction opposite the direction in which the crucible drive unit 107 rotates the crucible assembly 102 (e.g., counter-rotation). In embodiments using iso-rotation, the crystal drive unit may rotate the pulling cable 118 in the same direction in which crucible drive unit rotates the crucible assembly 102.

The ingot puller apparatus 100 includes bottom insulation 110 and side insulation 124 to retain heat in the puller apparatus 100. In the illustrated embodiment, the ingot puller apparatus 100 includes one or more heater assemblies disposed externally to the crucible assembly 102. For example, the apparatus 100 may include a bottom heater 126 and/or a side heater 135 which may each be an electrically resistive heater. The bottom heater 126 is disposed below the crucible floor 129. The crucible assembly 102 may be moved to be in relatively close proximity to the bottom heater 126 to melt the solid silicon charged to the crucible assembly 102.

According to the Czochralski single crystal growth process, a quantity of solid-phase silicon such as polycrystalline silicon, or “polysilicon,” is initially charged to the crucible assembly 102. The semiconductor or solar-grade solid silicon that is introduced into the crucible assembly 102 is melted by heat provided from one or more heating assemblies. Once the melt 104 is fully formed, the seed crystal 122 is lowered and contacted with the surface 111 of the melt 104. The pulling mechanism 114 is operated to pull the seed crystal 122 from the melt 104. The resulting ingot 113 includes a crown portion 142 in which the ingot transitions and tapers outward from the seed crystal 122 to reach a target diameter. The ingot 113 includes a constant diameter portion 145 or cylindrical “main body” of the crystal which is grown by increasing the pull rate. The main body 145 of the ingot 113 has a relatively constant diameter. The ingot 113 includes a tail or end-cone (not shown) in which the ingot tapers in diameter after the main body 145. When the diameter becomes small enough, the ingot 113 is then separated from the melt 104.

The crystal growth process may be a batch process in which solid silicon is initially added to the crucible assembly 102 to form a silicon melt without additional solid-silicon being added to the crucible assembly 102 during crystal growth. In other embodiments, the crystal growth process is a continuous Czochralski process in which an amount of silicon is added to the crucible assembly during ingot growth.

The ingot puller apparatus 100 includes a side heater 135 and a susceptor 106 that encircles the crucible assembly 102 to maintain the temperature of the melt 104 during crystal growth. The side heater 135 is disposed radially outward to the crucible sidewall 131 as the crucible assembly 102 travels up and down the pull axis A. The side heater 135 and bottom heater 126 may be any type of heater that allows the side heater 135 and bottom heater 126 to operate as described herein. In some embodiments, the heaters 135, 126 are electrical resistance heaters. The side heater 135 and bottom heater 126 may be controlled by a control system (not shown) so that the temperature of the melt 104 is controlled throughout the pulling process.

The ingot puller apparatus 100 may include a reflector assembly 151. The reflector assembly 151 includes an opening 157 through which the single crystal silicon ingot 113 is pulled during ingot growth. The ingot puller apparatus 100 may include an inert gas system to introduce and withdraw an inert gas such as argon from the growth chamber 152.

The illustrated ingot puller apparatus 100 is an example and any ingot puller apparatus 100 that includes one or more hotzone components that are coated with hafnia may be used unless stated otherwise.

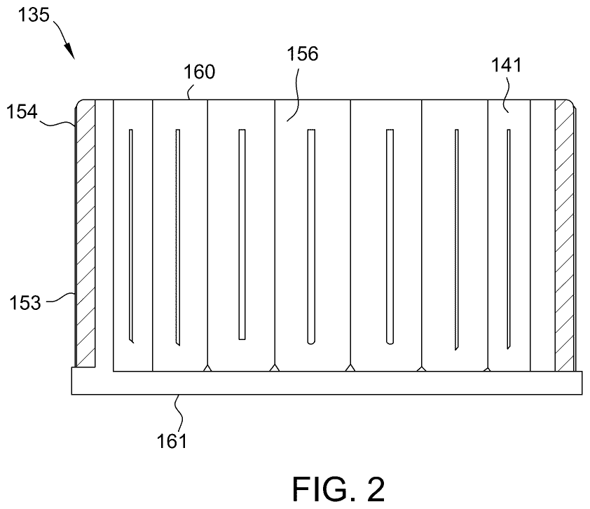

Referring now to FIG. 2, the heater assembly (shown as side heater 135) may include a graphite substrate 141 and a hafnia (HfO₂) coating 153 disposed on at least a portion of the substrate 141. For example, the coating 153 may be disposed on the outer surface 154 of the heater substrate 141 or the inner surface 156 of the substrate 141 or both the outer and inner surfaces 154, 156. The coating 153 may also be disposed on top and/or bottom surfaces 160, 161 of the graphite substrate 141.

Similar to the side heater 135 shown in FIG. 2, the bottom heater 126 (FIG. 1) may also include a graphite substrate with at least a portion of the surfaces of the graphite substrate having a hafnia coating disposed thereon. For example, the bottom surface and/or top surface of the bottom heater 126 may include a hafnia coating disposed thereon.

In embodiments in which the ingot puller apparatus 100 includes a bottom heater 126 and a side heater 135, both heaters 126, 135 may be coated with hafnia or only one of the heaters 126, 135 may be coated with hafnia.

As noted above, the ingot puller apparatus 100 includes graphite insulation that is disposed along one or more of the inner surfaces 173 of the ingot puller housing 108. For example, the apparatus 100 includes side insulation 124 disposed radially outward of the crucible assembly 102 and bottom insulation 110 that is disposed below the crucible assembly 102. The bottom insulation 110, side insulation 124 or both the bottom and side insulation 110, 124 may be coated with hafnia.

In some embodiments, a graphite exhaust port of the ingot puller apparatus 100 is coated with hafnia.

In some embodiments of the present disclosure, the reflector assembly 151 includes one or more surfaces that are coated with hafnia. The reflector assembly 151 may include molybdenum-coated graphite with hafnia being disposed on one or more molybdenum surfaces.

The hafnia coatings described above may be sufficiently dense to reduce the likelihood that hafnia flakes from the graphite material and/or have a sufficient thickness to prevent contact of the ambient with graphite. For example, the density may be at least 75% to 100% of the theoretical density of hafnia, or 85% to 95% or 90% to 100% of the theoretical density.

The hafnia coating may be plasma sprayed or deposited by chemical vapor deposition processes. In other embodiments, brushing or spraying methods may be used to apply the hafnia coating. In some embodiments, after applying the coating, the coating may be heated to improve bonding with graphite. For example, the coating may be heated to a temperature of from 1300° C. to 1800° C.

The hafnia coating may be applied with one or more additional components incorporated therein. For example, the coating may be applied with a densification promoter such as yttria, ceria, lanthanum or combination thereof incorporated therein. Other components that could be applied with hafnia include Al₂O₃, CaO, Ta₂O₃ and multi-component sintering aids.

Compared to conventional ingot puller components, the hafnia-coated components of the present disclosure have several advantages. The hafnia coatings are mostly non-reactive with the crystal puller ambient (e.g., SiO). The hafnia coatings bond well with graphite which allows the coatings to be used above the melt. Hafnia is believed to have a small segregation coefficient in silicon melts which minimizes segregation into the growing crystal if melt contamination occurs. Both plasma sprayed and CVD application methods provide dense coatings that can be used on multiple ingot puller runs. By coating the heater apparatus with hafnia (e.g., side heater and/or bottom heater), “wear-in” of the heater may be eliminated (i.e., erosion of the graphite with the upper region being thinned relative to the lower region) and axial temperature control in the crystal is improved (e.g., because of less axial changes in the heater thickness over time due to the wear-in effect).

### EXAMPLES

The processes of the present disclosure are further illustrated by the following Examples. These Examples should not be viewed in a limiting sense.

### Example 1: Comparative Reactivity of Uncoated Graphite and Graphite Coated with Hafnia in the Ingot Puller Apparatus

A graphite coupon was coated with hafnia by plasma spraying and a second coupon was coated with hafnia by CVD. A fused quartz cube was placed on each coated coupon and a third fused quartz cube was placed on an uncoated graphite coupon. The coated coupons and the third coupon that was uncoated were heated with the fused quartz cubes under vacuum at 10 torr in an argon ambient to a temperature of 1600° C. for five hours.

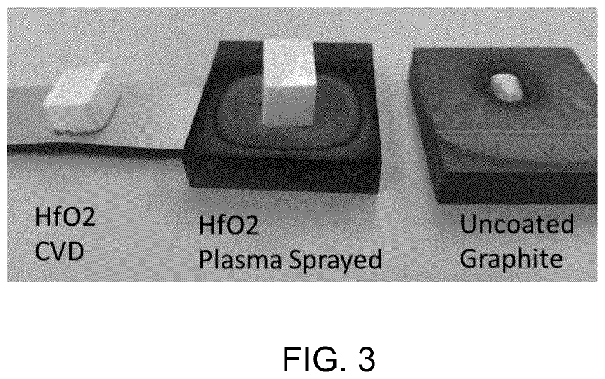

As shown in FIG. 3, the quartz cube reacted considerably with the uncoated graphite compared to the quartz cubes supported by the hafnia-coated graphite coupons. The amount of quartz cube that reacted was estimated by measuring the quartz cube volume and calculating a percentage of the remaining volume of the quartz cube. For the uncoated graphite, the quartz cube lost 93% of its mass. For the hafnia coated graphite cases, the cube lost less than 3% of its mass. Use of a hafnia coating on the contact surface significantly reduced the reactivity of the interface. Post heating, it was possible to separate the quartz from the hafnia surfaces; whereas on the uncoated surface, quartz at least partially adhered to the coupon. Also, post heating, for the plasma sprayed and the CVD coatings, the coating was well adhered to the graphite substrate which indicates potential use of the coating in multiple crystal growth runs without recoating.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing [s] shall be interpreted as illustrative and not in a limiting sense.

What is claimed is:

1. An ingot puller apparatus for producing a single crystal silicon ingot, ingot puller apparatus comprising:
a crucible assembly for holding a silicon melt;
an ingot puller housing that defines a growth chamber for pulling a silicon ingot from the silicon melt, the crucible assembly being disposed within the growth chamber; and
a heater assembly disposed external to the crucible assembly, the heater assembly being an electrically resistive heater comprising a graphite substrate, the graphite substrate being coated with hafnia.

2. The ingot puller apparatus as set forth in claim 1 wherein the heater assembly is a side heater disposed radially outward to the crucible assembly.

3. The ingot puller apparatus as set forth in claim 1 wherein the heater assembly is a bottom heater disposed below the crucible assembly.

4. The ingot puller apparatus as set forth in claim 1 wherein the heater assembly is a first heater assembly, the first heater assembly being disposed radially outward to the crucible assembly, the ingot puller apparatus comprising a second heater assembly, the second heater assembly being disposed below the crucible assembly.

5. An ingot puller apparatus for producing a single crystal silicon ingot, ingot puller apparatus comprising:
a crucible assembly for holding a silicon melt;
an ingot puller housing that defines a growth chamber for pulling a silicon ingot from the silicon melt, the crucible assembly being disposed within the growth chamber; and
insulation disposed along one or more inner surfaces of the ingot puller housing, the insulation comprising graphite coated with hafnia.

6. The ingot puller apparatus as set forth in claim 5 wherein the insulation is bottom insulation disposed below the crucible assembly.

7. The ingot puller apparatus as set forth in claim 5 wherein the insulation is side insulation disposed radially outward of the crucible assembly.

8. An ingot puller apparatus for producing a single crystal silicon ingot, ingot puller apparatus comprising:
a crucible assembly for holding a silicon melt;
an ingot puller housing that defines a growth chamber for pulling a silicon ingot from the silicon melt, the crucible assembly being disposed within the growth chamber; and
a reflector assembly having an opening for receiving the single crystal silicon ingot as the ingot is pulled through the reflector assembly, the reflector assembly comprising molybdenum coated with hafnia.

9. The ingot puller apparatus as set forth in claim 8 comprising a graphite substrate coated with molybdenum, the molybdenum being coated with hafnia.
